(19) United States
(12) Patent Application Publication
(10) Pub. No.: US 2006/0043367 A1
(43) Pub. Date: Mar. 2, 2006

(54) SEMICONDUCTOR DEVICE AND METHOD OF FABRICATING A LOW TEMPERATURE POLY-SILICON LAYER

(76) Inventors: Mao-Yi Chang, Tao-Yuan City (TW); Yi-Wei Chen, I-Lan Hsien (TW)

Correspondence Address: NORTH AMERICA INTELLECTUAL PROPERTY CORPORATION, P.O. BOX 506, MERRIFIELD, VA, 22116, US

(21) Appl. No.: 10/904,157

(22) Filed: Oct. 27, 2004

(30) Foreign Application Priority Data
Sep. 1, 2004 (TW) 093126382

(51) Int. Cl. H01L 29/76; H01L 23/34; H01L 29/04

(52) U.S. Cl. 257/66; 257/70; 257/712; 257/706; 257/713

(57) ABSTRACT

A method of fabricating a low temperature poly-silicon (LTPS). A plurality of semiconductor heat sinks are formed over a substrate. A buffer layer and an amorphous silicon layer are formed over the substrate and the semiconductor heat sinks. Following that, a laser crystallization process is performed to transform the amorphous silicon layer into a poly-silicon layer.

### BACKGROUND OF INVENTION

1. Field of the Invention

The present invention is generally related to a semiconductor device and a method of fabricating a low temperature poly-silicon (LTPS) layer, and more particularly, to a semiconductor device and a method of fabricating an LTPS layer using lateral growth.

2. Description of the Prior Art

In the process of fabricating thin film transistor (TFT) liquid crystal displays (LCDs), because the heat resistance of the glass substrate is often under 600° C., and the deposition temperature of the LTPS layer is between 575-650° C., fabricating a poly-silicon layer directly under high temperatures may cause deformation on the glass substrate. As a result, a method of crystallizing an amorphous silicon layer has been gradually adopted in the present fabrication of LTPS layers of TFT LCDs.

A conventional LTPS layer is fabricated on an insulation substrate, and the insulation substrate must be made of materials pervious to light, such as glass substrates, quartz substrates, or plastic substrates. In conventional methods, an amorphous silicon layer is formed on the insulation substrate, and then an excimer laser annealing (ELA) process is performed, for making the amorphous silicon layer crystallize into the poly-silicon layer. In the process of ELA, the amorphous silicon layer melts and crystallizes quickly through the absorption of laser (deep ultra violate light) to form the poly-silicon layer. This kind of fast absorption caused by a short-pulsed laser affects the surface of the amorphous silicon layer only, but does not affect the insulation substrate. Therefore, the insulation substrate is kept at a low temperature.

Because the quality of the amorphous silicon layer has great influence on the property of the poly-silicon TFT subsequently formed, parameters in the process of the amorphous silicon layer deposition should be controlled carefully in order to form an amorphous silicon layer with low hydrogen content, high uniformity of film thickness, and low surface roughness. In addition, because the poly-silicon layer formed from the crystallization of the amorphous silicon layer serves as a semiconductor layer in the TFT to define a source, a drain, and a channel region between the source and the drain, the quality of the poly-silicon layer has direct influence on electrical performance. For example, the grain size of the poly-silicon layer is an important factor that can influence the quality of the poly-silicon layer.

The grain size of the poly-silicon fabricated by typical ELA is about 3000 Å, and the direction of grain growth cannot be efficiently controlled. Presently, there are related publications disclosing that bigger and directional crystals can be reached by generating a temperature gradient on the surface of the amorphous silicon layer. For example, a method of forming a high thermal conductivity material layer under the amorphous silicon layer is disclosed in U.S. Pat. No. 5,851,862, wherein the high thermal conductivity material layer may consist of materials such as aluminum nitride, boron nitride, or diamond like carbon. In addition, a semiconductor element structure with a high thermal conductivity material layer formed under the semiconductor layer is disclosed in U.S. Pat. No. 6,555,875, wherein the high thermal conductivity material layer consists of insulation materials such as aluminum oxide (Al₂O₃), aluminum nitride, nitrogen oxide compounds (e.g. AlNₓO₁₋ₓ, AlSiON, LaSiON), boron nitride, or diamond like carbon. Because the high thermal conductivity material layer is able to absorb thermal energy during the laser illumination, a temperature gradient is generated between the amorphous silicon layer (semiconductor layer) adjacent to the high thermal conductivity material layer and other portions of the amorphous silicon layer. The portion of the amorphous silicon layer adjacent to the high thermal conductivity material layer has a higher rate of crystallization, while the other portions of the amorphous silicon layer have a lower rate of crystallization. Thus, grains grow horizontally from the portions adjacent to the high thermal conductivity material layer to other portions.

The insulation material with the high thermal conductivity can avoid the problem of diffusion of metal atoms into an element channel due to high temperature, which occurs when the conventional way of generating the thermal gradient by using metal materials as a reflection layer is adopted. However, the film formation of insulation materials, such as aluminum nitride, boron nitride, or diamond like carbon, has to be performed under a high temperature for promoting the thermal conductivity, and there are difficulties in etching while defining the pattern. Therefore, there are still difficulties in practice.

### SUMMARY OF INVENTION

It is an object of the present invention to provide a semiconductor device and a method of fabricating an LTPS layer, which can avoid the problem that occurs when conventionally applying metal or insulation material to fabricate the LTPS layer.

According to the present invention, a plurality of semiconductor heat sinks are formed over a substrate, a buffer layer and an amorphous silicon layer are thereafter formed over the substrate and the semiconductor heat sinks. Subsequently, a laser crystallization process is performed to transform the amorphous silicon layer into a poly-silicon layer.

It is an advantage of the present invention that the semiconductor heat sinks are able to absorb heat from the amorphous silicon layer quickly during the laser crystallization process, thus generating a temperature gradient between the amorphous silicon layer adjacent to the semiconductor heat sinks and other portions of the amorphous silicon layer for promoting the lateral growth of the grains. Particularly, the semiconductor heat sinks can be fabricated using semiconductor materials and apparatuses in a typical LTPS process. Therefore, the present invention does not greatly affect the manufacturing cost and the complexity of the manufacturing process. Consequently, the present invention is highly practical, and is able to completely prevent the problems of the conventional method of fabricating the LTPS layer with metals or insulation materials.

These and other objects of the present invention will no doubt become obvious to those of ordinary skill in the art after reading the following detailed description of the preferred embodiment that is illustrated in the various figures and drawings.

### BRIEF DESCRIPTION OF DRAWINGS

FIGS. 1a-1c show schematic views illustrating a method of fabricating an LTPS layer according to a first embodiment of the present invention;

FIGS. 2a-2d show schematic views illustrating a method of fabricating an LTPS layer according to a second embodiment of the present invention;

FIG. 3 shows a schematic view illustrating a TFT structure according to the present invention;

FIG. 4 shows a schematic view illustrating another TFT structure according to the present invention;

FIG. 5 shows a schematic view illustrating a semiconductor device according to the present invention; and

FIG. 6 shows a schematic view illustrating another semiconductor device according to the present invention.

### DETAILED DESCRIPTION

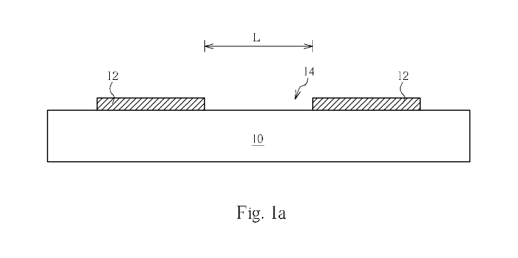

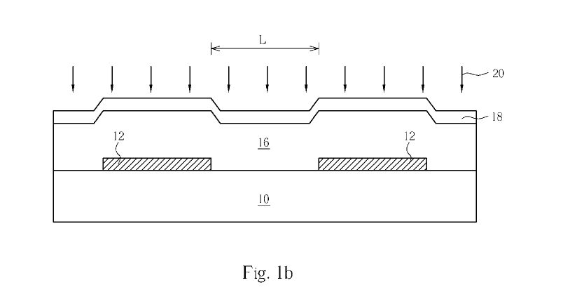

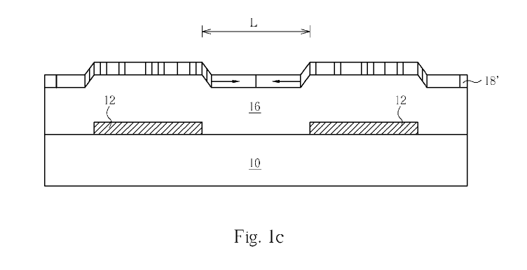

Please refer to FIGS. 1a-1c. FIGS. 1a-1c are schematic views illustrating a method of fabricating an LTPS layer according to a first embodiment of the present invention. As shown in FIG. 1a, the method of the present invention provides a substrate 10, such as a glass substrate, a quartz substrate, or a plastic substrate, and then forms a semiconductor layer (not shown) with a high thermal conductivity over the substrate 10. Following that, portions of the semiconductor layer are removed with a photolithographic and etching process, to generate at least one opening 14 within the semiconductor layer, and to make the remaining semiconductor layer form a plurality of semiconductor heat sinks 12. The opening 14 defines a channel region L, and the semiconductor heat sinks 12 are created around the channel region L. The semiconductor heat sinks 12 are able to absorb thermal energy during a later laser illumination and generate a temperature gradient on an amorphous silicon layer for facilitating the reduction of the amount of grain boundaries in the channel region L.

A typical LTPS process can be utilized in the fabrication of the semiconductor heat sinks 12. For example, the semiconductor heat sinks 12 can be fabricated by using a plasma enhanced chemical vapor deposition (PECVD) method. The semiconductor heat sinks 12 are composed of materials selected from the group consisting of silicon, germanium, silicon germanium, gallium nitride, and gallium arsenide, and a silicon layer is preferred to form the semiconductor heat sinks 12. However, according to the present invention, the method of fabricating the semiconductor heat sinks 12 is not limited to PECVD, but also includes fabricating the semiconductor heat sinks 12 by controlling process recipes so as to form the semiconductor heat sinks 12 with different thermal conductivities (10-30 W/m-k). For example, a poly-silicon layer formed by using ELA has a higher thermal conductivity than a poly-silicon layer formed by using a high temperature oven. In addition, because the thermal conduction in a crystalline solid mostly depends on lattice vibration, the thermal conductivity of a substance is affected by the structure of the lattice, including grain boundaries, stacking faults, and the number of various defects. For example, the thermal conductivity of a single-crystalline silicon structure is higher than that of a poly-silicon structure, while the thermal conductivity of a poly-silicon structure is higher than that of an amorphous silicon structure. As a result, the semiconductor heat sinks 12 according to the present invention can be formed with different lattice structures of single-crystalline silicon, poly-silicon, amorphous silicon, or doped silicon depending on the process adopted or requirements of products, so as to provide different thermal conductivities.

After completing the fabrication of the semiconductor heat sinks 12, as shown in FIG. 1b and FIG. 1c, a buffer layer 16 and an amorphous silicon layer 18 are sequentially formed over the substrate 10 and the semiconductor heat sinks 12, and a laser crystallization process is performed, for example, illuminating the amorphous silicon layer 18 with an excimer laser 20 to make the amorphous silicon layer 18 crystallize into a poly-silicon layer 18′. The buffer layer 16 and the amorphous silicon layer 18 can be formed by using PECVD, wherein the buffer layer 16 can be a silicon oxide layer for insulating the semiconductor heat sinks 12 from the amorphous silicon layer 18. According to the present invention, after forming the buffer layer 16 and the amorphous silicon layer 18, a dehydrogenation process is performed in a high temperature furnace under a temperature higher than 400° C. to reduce the hydrogen content in the amorphous silicon layer 18. During the performance of the laser crystalline process, the semiconductor heat sinks 12 with the high thermal conductivity absorb thermal energy quickly, for forming a temperature gradient between the portion of the amorphous silicon layer 18 above the semiconductor heat sinks 12 and the portion of the amorphous silicon layer 18 within the channel region L. Because the semiconductor heat sinks 12 absorb thermal energy quickly, the portion of the amorphous silicon layer 18 above the semiconductor heat sinks 12 has a higher crystallization rate, while the portion of the amorphous silicon layer 18 within the channel region L has a lower crystallization rate. As a result, grains grow in a lateral direction (as indicated by the arrow shown in FIG. 1c) from above the semiconductor heat sinks 12 toward the channel region L, to form the poly-silicon layer 18′. The poly-silicon layer 18′ fabricated according to the present invention has bigger grains and a smaller amount of grain boundaries, so the advantages of promoting the mobility of carriers and improving element properties can be reached.

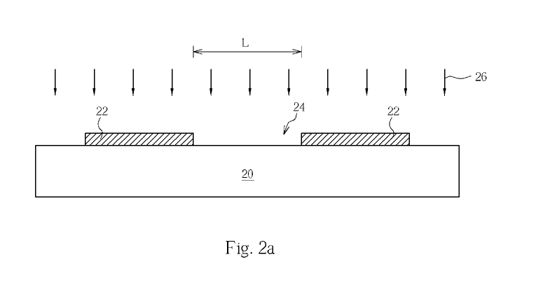

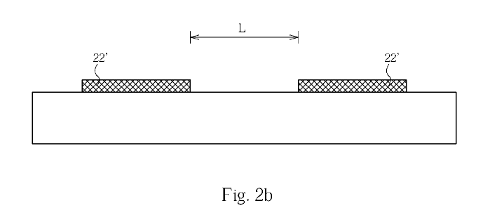

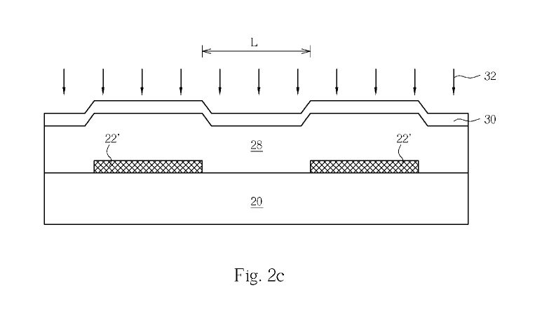

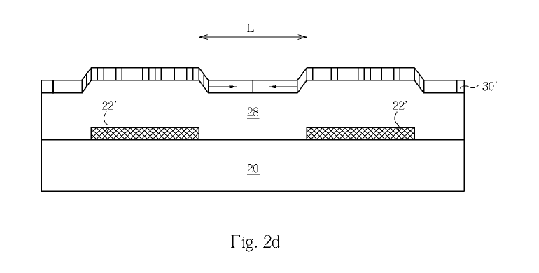

Please refer to FIGS. 2a-2d. FIGS. 2a-2d are schematic views of a method of fabricating an LTPS layer according to a second embodiment of the present invention. As shown in FIG. 2a, the method of the present invention provides a substrate 20, such as a glass substrate, a quartz substrate, or a plastic substrate, and then forms a semiconductor layer (not shown) with a high thermal conductivity over the substrate 20. Following that, portions of the semiconductor layer are removed with a photolithographic and etching process, to generate at least one opening 24 within the semiconductor layer, and to make the remaining semiconductor layer form a plurality of semiconductor heat sinks 22. The opening 24 defines a channel region L, and the semiconductor heat sinks 22 are around the channel region L. The semiconductor heat sinks 22 are able to absorb thermal energy during a later laser illumination and generate a temperature gradient on an amorphous silicon layer for facilitating the reduction of the amount of grain boundaries in the channel region L.

In the present embodiment, the semiconductor heat sinks 22 can be amorphous semiconductor materials formed by using PECVD. The semiconductor heat sinks 22 are composed of materials selected from the group consisting of silicon, germanium, silicon germanium, gallium nitride, and gallium arsenide, and wherein a silicon layer is preferred to form the semiconductor heat sinks 22.

As shown in FIG. 2a and FIG. 2b, a laser crystallization process is subsequently performed. For example, the amorphous semiconductor heat sinks 22 are illuminated with an excimer laser 26 to transform the semiconductor heat sinks 22 into crystallized semiconductor heat sinks 22′, such as transforming the semiconductor heat sink 22 from amorphous silicon into poly-silicon. In other embodiments of the present invention, the laser crystallization process can be substituted by other thermal processes or light illumination processes depending on actual needs of the process, and the semiconductor heat sinks 22 can be illuminated by a laser crystallization process to be transformed into the semiconductor heat sinks 22′ first, and then its pattern can be defined with the lithographic and etching process.

After completing the fabrication of the semiconductor heat sinks 22′, as shown in FIG. 2c and FIG. 2d, a buffer layer 28 and an amorphous silicon layer 30 are sequentially formed over the substrate 20 and the semiconductor heat sinks 22′, and a laser crystallization process is performed again, for example, illuminating the amorphous silicon layer 30 with an excimer laser 32 to make the amorphous silicon layer 30 crystallize into a poly-silicon layer 30′. The buffer layer 28 and the amorphous silicon layer 30 can be formed by using PECVD, wherein the buffer layer 28 can be a silicon oxide layer for insulating the semiconductor heat sinks 22′ from the amorphous silicon layer 30.

During the excimer laser 32 illumination, the semiconductor heat sinks 22′ with the high thermal conductivity absorb thermal energy quickly to generate a temperature gradient between the portion of the amorphous silicon layer 30 above the semiconductor heat sinks 22′ and the portion of the amorphous silicon layer 30 within the channel region L. Because the semiconductor heat sinks 22′ absorb thermal energy quickly, the portion of the amorphous silicon layer 30 above the semiconductor heat sinks 22′ has a higher crystallization rate, while the portion of the amorphous silicon layer 30 within the channel region L has a lower crystallization rate. As a result, grains grow in a lateral direction (as indicated by the arrow shown in FIG. 2d) from above the semiconductor heat sinks 22′ toward the channel region L, to form a poly-silicon layer 30′. The poly-silicon layer 30′ fabricated according to the present invention has bigger grains and a smaller amount of grain boundaries, so the advantages of promoting the mobility of carriers and improving element properties can be reached.

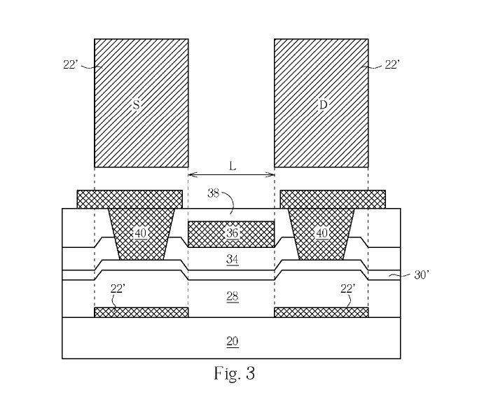

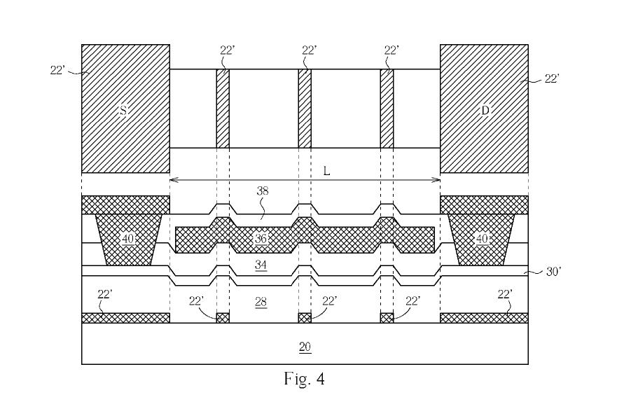

According to the present invention, after the fabrication of the poly-silicon layer is completed, a TFT fabrication process is performed. Please refer to FIG. 3 and FIG. 4. FIG. 3 and FIG. 4 are schematic views of a TFT structure according to the present invention. FIG. 4 is a schematic view of a TFT structure with a long channel, and the TFT in FIG. 4 includes not only a plurality of semiconductor heat sinks 22′ deposited within the source/drain (S/D) region around the channel region L, but also a plurality semiconductor heat sinks 22′ deposited within the channel region L, to control the number of grain boundaries within the channel region L. As shown in FIG. 3 and FIG. 4, according to the present invention, after the poly-silicon layer 30′ in FIG. 2d is completed, elements can be formed over the poly-silicon layer 30′, wherein the elements comprise a gate insulation layer 34, a gate (the first metal layer) 36, an inter-layer-dielectric layer 38, and a S/D conducting wire (the second metal layer) 40, to complete the fabrication of the LTPS TFT.

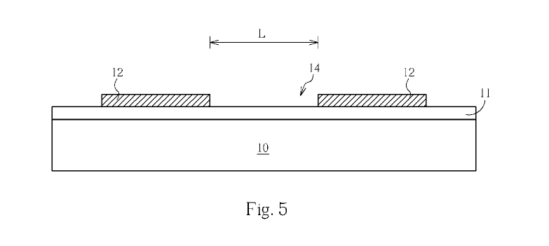

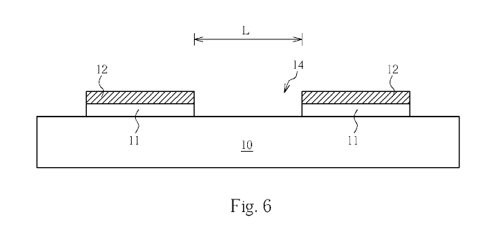

In addition, to enhance the adhesion between the semiconductor heat sinks and the substrate, an adhesion layer is formed between the semiconductor heat sinks and the substrate in other embodiments of the present invention. Please refer to FIG. 5 and FIG. 6. FIG. 5 and FIG. 6 are schematic views of a semiconductor device with an adhesion layer according to the present invention. As shown in FIG. 5 and FIG. 6, the semiconductor device comprises an adhesion layer 11 deposited between the semiconductor heat sinks 12 and the substrate 10 to improve the adhesion between the semiconductor heat sinks 12 and the substrate 10, and thereby to prevent the semiconductor heat sinks 12 from being stripped from the substrate 10 due to non-uniformly thermal conduction in portions of the semiconductor heat sinks 12 during the laser crystallization process or other thermal processes. In actual applications, the adhesion layer 11 can either totally cover the substrate 10, or the adhesion layer 11 can be cut to fit the semiconductor heat sinks 12, thus exposing portions of the substrate 10. In FIG. 5 and FIG. 6, the element numbers assigned to elements are the same as those shown in FIG. 1a, and FIG. 1b to FIG. 4 can be referred to for the subsequent processes.

Compared to the conventional methods of fabricating the LTPS, the present invention utilizes the semiconductor heat sinks to quickly absorb parts of the thermal energy from the amorphous silicon layer, so a temperature gradient is generated between the portion of the amorphous silicon layer around these semiconductor heat sinks and the other portions of the amorphous silicon layers, thus promoting the lateral growth of grains. Particularly, the semiconductor heat sinks can be fabricated using semiconductor materials and apparatuses in a typical LTPS process. Therefore the present invention does not greatly affect the manufacturing cost and the complexity of the manufacturing process. Consequently, the invention is highly practical, and is able to completely prevent the problem occurring in the conventional method of fabricating the LTPS layer with metals or insulation materials.

Those skilled in the art will readily observe that numerous modifications and alterations of the device and method may be made while retaining the teachings of the invention. Accordingly, the above disclosure should be construed as limited only by the metes and bounds of the appended claims.

1-6. (canceled)

7. A semiconductor device, comprising:
a substrate;
a plurality of semiconductor heat sinks disposed over the substrate;
a buffer layer disposed over the substrate and the semiconductor heat sinks; and
a poly-silicon layer disposed over the buffer layer.

8. The semiconductor device of claim 7, wherein the semiconductor heat sinks are materials selected from the group consisting of silicon, germanium, silicon germanium, gallium nitride, and gallium arsenide.

9. The semiconductor device of claim 7, wherein the semiconductor heat sinks comprise single-crystalline silicon, poly-silicon, amorphous silicon, or doped silicon.

10. The semiconductor device of claim 7, wherein the buffer layer comprises a silicon oxide layer.

11. The semiconductor device of claim 7, wherein the semiconductor heat sinks are disposed around a channel region.

12. The semiconductor device of claim 7, further comprising an adhesive layer disposed between the substrate and the semiconductor heat sinks.

13. The semiconductor device of claim 7, further comprising an adhesive layer disposed between the substrate, the semiconductor heat sinks and the buffer layer.
